(19) United States
(12) Patent Application Publication
(10) Pub. No.: US 2025/0081415 A1
(43) Pub. Date: Mar. 6, 2025

(54) ELECTRONIC DEVICE

(71) Applicant: Canaan Creative Co., LTD., Beijing (CN)

(72) Inventors: Fuxing LIU, Beijing (CN); Shaohua ZHANG, Beijing (CN); Huan YANG, Beijing (CN); Nangeng ZHANG, Beijing (CN)

(21) Appl. No.: 18/948,407

(22) Filed: Nov. 14, 2024

Related U.S. Application Data
(63) Continuation of application No. PCT/CN2023/090968, filed on Apr. 26, 2023.

(30) Foreign Application Priority Data
Aug. 24, 2022 (CN) 202211021806.X
Aug. 24, 2022 (CN) 202222249947.9

(51) Int. Cl. H05K 7/20; H05K 1/02

(52) U.S. Cl. CPC H05K 7/209; H05K 1/0203; H05K 7/20409

(57) ABSTRACT

An electronic device, comprising: a housing; working assemblies mounted in the housing, wherein each working assembly comprises a circuit board and a radiator, the circuit board comprising a substrate and a plurality of working chips provided on the substrate; and the working assemblies are detachably mounted within the housing; a control board connected to the circuit board; and a power source configured to supply power to the circuit board.

### CROSS-REFERENCES TO RELATED APPLICATION

This application is a continuation application of International Application No. PCT/CN2023/090968, filed on Apr. 26, 2023, and titled “Electronic Device,” which claims priority to Chinese Patent Application No. 202211021806.X, filed with the China National Intellectual Property Administration on Aug. 24, 2022, and titled “Electronic Device,” and to Chinese Patent Application No. 202222249947.9, filed with the China National Intellectual Property Administration on Aug. 24, 2022, and titled “Electronic Device,” all of which are hereby incorporated by reference in their entirety.

### TECHNICAL FIELD

The present disclosure relates to the technical field of heat dissipation, and in particular, to an electronic device.

### BACKGROUND

With the development of artificial intelligence and big data technologies, the requirements for computing power of electronic devices become higher and higher. In order to meet the requirements for computing power, a plurality of working chips are generally arranged on a circuit board of an electronic device for parallel computing.

### SUMMARY

Embodiments of the present disclosure provide an electronic device. The electronic device includes: a housing; working assemblies mounted in the housing, wherein each working assembly includes a circuit board and a radiator, the circuit board including a substrate and a plurality of working chips provided on the substrate; and the working assemblies are detachably mounted within the housing; a control board connected to the circuit board; and a power source configured to supply power to the circuit board.

In an embodiment, the electronic device further includes: a plurality of thermal conductive elements, wherein each thermal conductive element covers at least two adjacent working chips and a region between the adjacent working chips; and the radiator includes a heat dissipation main body and heat dissipation fins, wherein the heat dissipation main body includes a first surface and a second surface opposite to each other, the first surface is connected to the heat dissipation fins, and the second surface is provided with a plurality of bosses, wherein the bosses are in contact with at least one of the thermal conductive elements, and an extension direction of the bosses is the same as an extension direction of the thermal conductive elements.

In an embodiment, the plurality of working chips are distributed in rows and columns, an average spacing between the plurality of working chips in a row direction is greater than an average spacing between the plurality of working chips in a column direction, and the thermal conductive elements extend in the column direction.

In an embodiment, the plurality of working chips form a plurality of working chip columns, voltage regulation circuits are further provided on the substrate, and components of at least some of the voltage regulation circuits are distributed among the working chip columns.

In an embodiment, the plurality of working chips are distributed in rows and columns, an average spacing between the plurality of working chips in a row direction is less than an average spacing between the plurality of working chips in a column direction, and the thermal conductive elements extend in the row direction.

In an embodiment, the plurality of working chips form a plurality of working chip rows, voltage regulation circuits are further provided on the substrate, and components of at least some of the voltage regulation circuits are distributed among the working chip rows.

In an embodiment, the thermal conductive elements extend in a direction perpendicular to a heat dissipation direction.

In an embodiment, in the heat dissipation direction, spacing between at least some of adjacent working chips is gradually increased.

In an embodiment, the housing encloses a heat dissipation air duct, the circuit board and the radiator are both provided in the heat dissipation air duct, and the heat dissipation direction is an air direction of the heat dissipation air duct.

In an embodiment, the spacing between at least some of adjacent working chips is positively correlated with a distance from the adjacent working chips to an air inlet of the heat dissipation air duct.

In an embodiment, an inner cavity of the radiator accommodates a heat dissipation medium, and the heat dissipation direction is a flowing direction of the heat dissipation medium.

In an embodiment, the respective working chips have the same size, and/or the respective working chips have the same heating area.

In an embodiment, at least one metal piece is provided between the adjacent working chips connected in series, and a thermal conductive element between the adjacent working chips covers the metal piece.

In an embodiment, a projection of a boss on the substrate corresponds to the metal piece.

In an embodiment, a projection of the thermal conductive element on the substrate corresponds to the metal piece between the adjacent working chips.

In an embodiment, a thickness of the metal piece is less than or equal to a thickness of a working chip, and a thickness direction of the metal piece and a thickness direction of the working chip are perpendicular to the substrate.

In an embodiment, the housing encloses a heat dissipation air duct, and the circuit board and the radiator are both provided in the heat dissipation air duct; the electronic device further includes a seal provided at end portions of the radiator and the circuit board close to the air inlet of the heat dissipation air duct, wherein the seal extends in the direction perpendicular to the air direction of the heat dissipation air duct.

In an embodiment, the seal includes: a seal body abutting against the end portions of the circuit board and the radiator close to the air inlet; and a seal protruding portion protruding from the seal body and located at a gap between the radiator and the circuit board.

In an embodiment, the seal protruding portion is an integrated member extending in a length direction of the seal body, and the length direction of the seal body is perpendicular to the air direction.

In an embodiment, the seal protruding portion includes a plurality of sub-protruding portions arranged in a length direction of the seal body, and the length direction of the seal body is perpendicular to the air direction.

In an embodiment, protrusion members are formed on the seal protruding portion, and a protruding direction of the protrusion members is perpendicular to the circuit board.

In an embodiment, a protrusion member is an integrated member extending in a length direction of the seal protruding portion, and the length direction of the seal protruding portion is perpendicular to the air direction.

In an embodiment, a protrusion member includes a plurality of sub-protrusion members arranged in a length direction of the seal protruding portion, and the length direction of the seal protruding portion is perpendicular to the air direction.

In an embodiment, an air guide portion is formed on a surface of the seal body facing away from the seal protruding portion.

In an embodiment, a cross section of the air guide portion is in a triangular or semicircular shape, and the cross section of the air guide portion is perpendicular to the circuit board.

In an embodiment, a seal protruding towards the circuit board is formed at an end portion of the radiator close to the air inlet, and the seal is in contact with the end portion of the circuit board close to the air inlet.

In an embodiment, the plurality of working chips form a plurality of working chip rows, an extension direction of the working chip rows is perpendicular to the air direction, and an extension length of the seal is greater than a length of the working chip rows.

In an embodiment, an extension length of the seal is less than a length of the circuit board in the direction perpendicular to the air direction.

In an embodiment, the circuit board is a single-layer circuit board, and the circuit board further includes: at least one bridging element provided at an intersection of circuit connection lines, wherein the bridging element includes a zero-ohm resistor and/or a zero-ohm metal patch.

In an embodiment, the zero-ohm resistor is provided opposite to a recess portion on the radiator.

In an embodiment, the electronic device further includes a control board, and a signal transmission circuit provided on the substrate, wherein the signal transmission circuit includes: N stages of working circuits connected in series, wherein each working circuit respectively includes at least one working chip, where N is an integer greater than 1, a first-stage working circuit is connected to a first system voltage, and an Nth-stage working circuit is connected to a second system voltage, the second system voltage being higher than the first system voltage; and a signal voltage conversion circuit, wherein a first input/output end of the signal voltage conversion circuit is connected to the Nth-stage working circuit, and a second input/output end of the signal voltage conversion circuit is connected to the control board; wherein the signal voltage conversion circuit is configured to perform voltage conversion on a control board signal sent by the control board and then send the converted control board signal to the N stages of working circuits; alternatively, the signal voltage conversion circuit is configured to perform voltage conversion on working circuit signals sent by the N stages of working circuits and then send the converted working circuit signals to the control board.

In an embodiment, the first-stage working circuit is configured to receive the control board signal, and the signal voltage conversion circuit is configured to send a working circuit signal of the Nth-stage working circuit to the control board.

In an embodiment, the signal transmission circuit further includes: a plurality of voltage regulation circuits connected to at least some stages of working circuits in one-to-one correspondence, wherein each voltage regulation circuit respectively includes at least one power source chip, and is configured to provide at least one regulation voltage for the connected working circuit.

In an embodiment, the signal voltage conversion circuit includes a first power supply end and a first grounding end, which are respectively connected to a regulation voltage power supply end of the Nth-stage working circuit and a grounding end of the Nth-stage working circuit.

In an embodiment, the signal voltage conversion circuit further includes a second power supply end and a second grounding end, which are respectively connected to a power supply end of the control board and a grounding end of the control board.

In an embodiment, the signal voltage conversion circuit further includes a second power supply end and a second grounding end, which are respectively connected to a regulation voltage power supply end of the first-stage working circuit and a grounding end of the first-stage working circuit.

The foregoing summary is for the purpose of illustration only and is not intended to be limiting in any way. In addition to the illustrative aspects, embodiments, and features described above, further aspects, embodiments, and features of the present disclosure will become readily apparent by reference to the drawings and the following detailed description.

### BRIEF DESCRIPTION OF THE DRAWINGS

In the drawings, like reference signs designate identical or similar parts or elements throughout the multiple figures unless otherwise specified. The figures are not necessarily drawn to scale. It should be understood that these figures depict only some embodiments in accordance with the present disclosure and should not be taken as limiting the scope of the present disclosure.

FIG. 1 shows a schematic diagram of an electronic device according to an embodiment of the present disclosure;

FIGS. 2, 3, 4, 5 and 6 show schematic diagrams of circuit boards according to embodiments of the present disclosure, respectively;

FIGS. 7, 8, 9, 10 and 11 show schematic diagrams of electronic devices according to embodiments of the present disclosure, respectively;

FIG. 12 shows a schematic diagram of a circuit board according to an embodiment of the present disclosure;

FIGS. 13A, 13B and 13C, and FIGS. 14A, 14B and 14C show schematic diagrams of seals according to embodiments of the present disclosure, respectively;

FIGS. 15, 16 and 17 show circuit diagrams of signal transmission circuits according to embodiments of the present disclosure;

FIG. 18 shows a diagram illustrating a working principle of a signal voltage conversion circuit according to an embodiment of the present disclosure;

FIGS. 19, 20 and 21 show circuit diagrams of signal transmission circuits according to embodiments of the present disclosure; and

FIG. 22 shows a schematic diagram of a circuit board according to an embodiment of the present disclosure.

### DETAILED DESCRIPTION

Hereinafter, only certain exemplary embodiments are briefly described. As recognizable to those skilled in the art, embodiments as described may be modified in various different ways without departing from the spirit or scope of the present disclosure. Accordingly, the drawings and description are to be regarded as illustrative in nature and not as restrictive.

In the related technologies, an electronic device includes a plurality of circuit boards, and in a case where one of the circuit boards needs to be maintained, all the plurality of circuit boards need to be removed at the same time, causing complex assembly and disassembly, and high maintenance cost. In addition, working chips generate a large amount of heat in a working process, and a radiator needs to be provided to dissipate heat for the circuit board. Therefore, how to improve the heat dissipation performance of the radiator for the circuit board becomes a technical problem to be solved urgently.

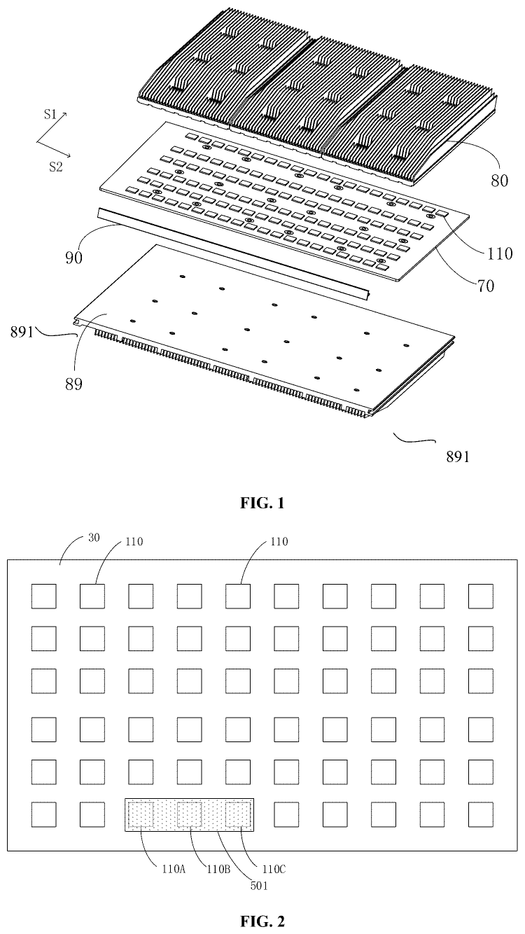

Embodiments of the present application provide an electronic device to solve or alleviate one or more technical problems in the existing technologies. As shown in FIG. 1, the electronic device includes a housing (not shown in the figure), working assemblies, a control board and a power source (not shown in the figure). The number of working assemblies is at least two, each working assembly is detachably mounted in the housing, and the control board is connected to the circuit board. Exemplarily, the control board is in signal connection with the circuit board, for example, the connection between the control board and the circuit board is implemented via a signal line, and the signal line may be a flexible flat cable. The working assemblies are mounted within the housing, where each working assembly includes a circuit board 70 and a radiator. The circuit board 70 includes a substrate 30 and a plurality of working chips 110 provided on the substrate 30. The power source is configured to supply power to the circuit board 70.

The radiator is located on the side of the circuit board where the working chips 110 are provided, and is configured to dissipate heat for the circuit board 70, such as the radiator 80. The radiator may also be located on the side of the circuit board where the working chips 110 are not provided, such as the radiator 89. The structures of the radiator 80 and the radiator 89 may be the same or different. Alternatively, both sides of the circuit board 70 are provided with working chips 110, and both sides of the circuit board 70 are provided with radiators, respectively.

Slideways 891 are provided at two opposite ends of the radiator, opposite sliding rails are provided on the housing, and the slideways 891 of the radiator fit the sliding rails on the housing to implement assembly and disassembly of working assemblies.

The radiator in this embodiment may be an air-cooled radiator, and may also be a liquid-cooled radiator, which is not limited in this embodiment.

Exemplarily, the respective working chips 110 have the same size, and the respective working chips 110 have the same length, width and thickness. In turns, the respective working chips 110 have the same heating area.

The circuit board in this embodiment may be a computing circuit board, so as to meet the requirements for computing power in the fields of artificial intelligence and big data. The electronic device in this embodiment may be a computing device, and is applied to scenarios with high computing burden in the fields of artificial intelligence and big data.

In an embodiment, the electronic device may include a plurality of thermal conductive elements, wherein a thermal conductive element covers at least two adjacent working chips 110 and a region between the adjacent working chips 110. In this way, heat can be dissipated not only for the working chips 110 but also for the substrate 30, thereby increasing the heat dissipation efficiency of the circuit board.

In an example, as shown in FIG. 2, one thermal conductive element 501 covers several working chips 110A, 110B and 110C, and regions between the working chips 110A, 110B and 110C. It should be noted that, in this embodiment, the number and size of the thermal conductive elements 501, and the number of working chips 110 covered thereby are not limited, which may be differently configured as actually needed.

In an embodiment, the plurality of working chips 110 are distributed in rows and columns, and the spacing between adjacent working chips 110 may be different, i.e. the sparse states based on the distribution of the working chips 110 may be different. The thermal conductive elements are adapted to extend in a distribution direction with small spacing.

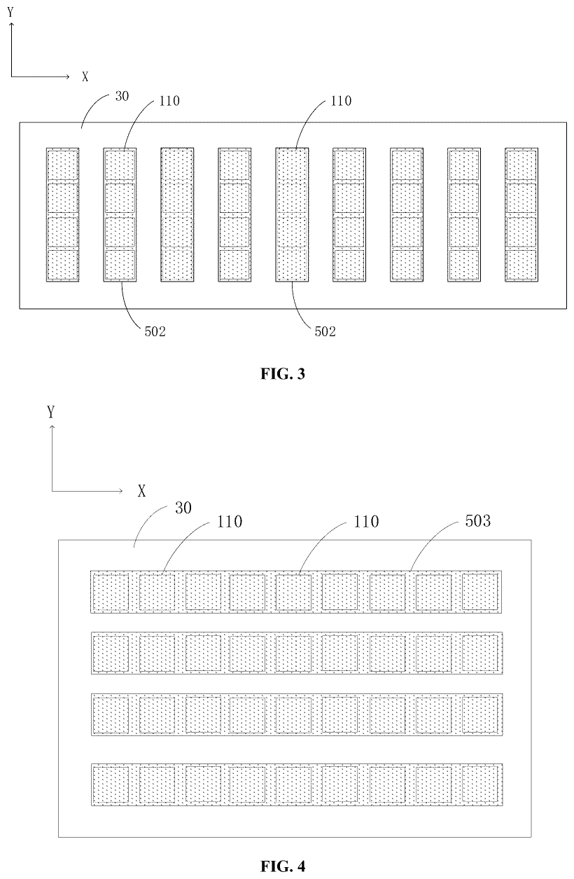

In an example, as shown in FIG. 3, the plurality of working chips 110 are distributed in rows and columns, the average spacing between the plurality of working chips 110 in a row direction X is greater than the average spacing between the plurality of working chips 110 in a column direction Y, and the thermal conductive elements 502 extend in the column direction Y. Thus, the area of the thermal conductive elements can be reduced, thereby saving the material for forming the thermal conductive elements.

In another example, as shown in FIG. 4, the average spacing between the plurality of working chips 110 in a row direction X is less than the average spacing between the plurality of working chips 110 in a column direction Y, and the thermal conductive elements 503 extend in the row direction X. Thus, the area of the thermal conductive elements can be reduced, thereby saving the material for forming the thermal conductive elements.

It should be noted that, in this embodiment, the number and size of the thermal conductive elements 502 and 503, and the number of working chips 110 covered thereby are not limited, which may be differently configured as actually needed.

Exemplarily, in this embodiment, the material of the thermal conductive elements may be silicone grease, silicone rubber, or a silicone rubber strip, that is, the thermal conductive elements may be a silicone grease layer or a silicone rubber layer, and coated on or attached to the surfaces of the plurality of working chips 110 and regions between the plurality of working chips 110.

In an embodiment, the plurality of working chips are distributed in rows and columns, the spacing between at least some of adjacent working chips is gradually increased in the heat dissipation direction of the radiator, and the thermal conductive elements extend in the direction perpendicular to the heat dissipation direction.

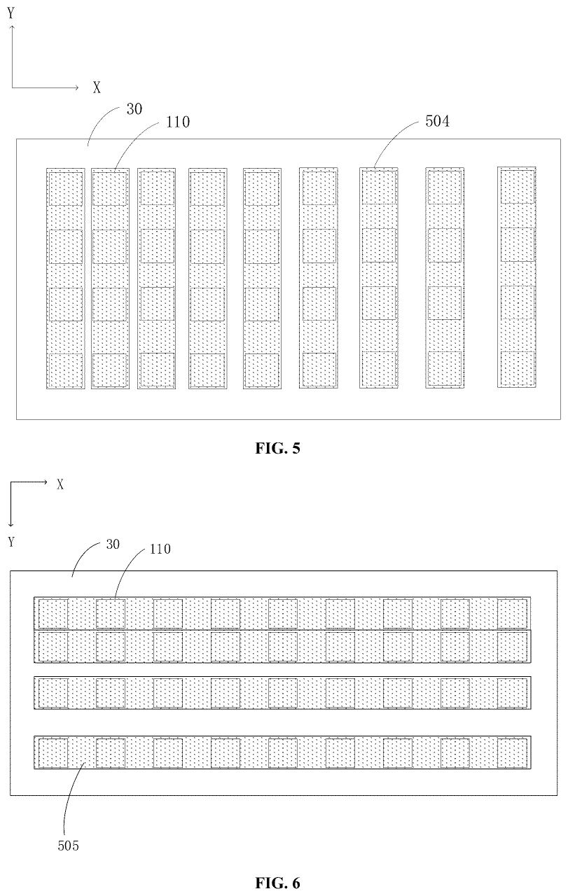

In an example, as shown in FIG. 5, the heat dissipation direction is parallel to the row direction X, the spacing between adjacent working chips 110 is gradually increased in the heat dissipation direction, and the thermal conductive elements 504 extend in the column direction Y.

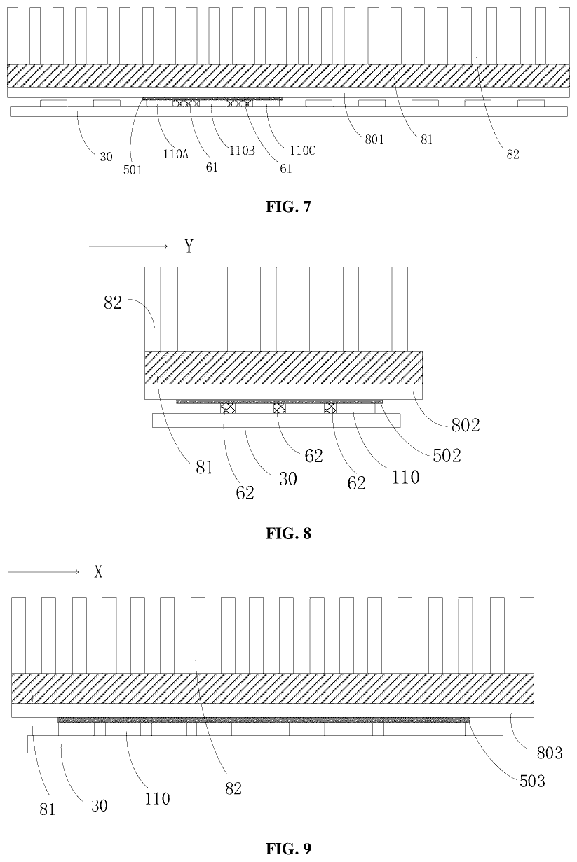

In another example, as shown in FIG. 6, the heat dissipation direction is parallel to the column direction Y, the spacing between adjacent working chips 110 is gradually increased in the heat dissipation direction, and the thermal conductive elements 505 extend in the row direction X.

Thus, the area of the thermal conductive elements can be reduced, thereby saving the material for forming the thermal conductive elements.

It should be noted that, in this embodiment, “gradually increased” should be understood as a variation trend of the spacing, that is, the spacing between adjacent working chips does not increase one by one, and the spacing between several adjacent working chips is allowed to decrease in the heat dissipation direction, as long as the spacing between adjacent working chips generally has an increase trend in the heat dissipation direction. For example, in order to provide avoidance for other components or provide other components, the spacing between several adjacent working chips may be decreased in the heat dissipation direction.

Exemplarily, the radiator may be an air-cooled radiator, for example, the housing is configured to enclose a heat dissipation air duct, and the circuit board and the radiator are both provided in the heat dissipation air duct, wherein the heat dissipation direction is an air direction of the heat dissipation air duct. For example, the heat dissipation air duct has an air inlet, and the spacing between adjacent working chips is positively correlated with the distance from the adjacent working chips to the air inlet, such that the spacing between adjacent working chips 110 is gradually increased in the heat dissipation direction.

Exemplarily, the radiator may also be a liquid-cooled radiator, and the inner cavity of the radiator accommodates a heat dissipation medium, wherein the heat dissipation direction is a flowing direction of the heat dissipation medium. Thus, the spacing between adjacent working chips 110 is gradually increased in the heat dissipation direction.

The heat dissipation efficiency of the heat dissipation channel is gradually decreased in the heat dissipation direction, and therefore the spacing between adjacent working chips 110 is gradually increased in the heat dissipation direction, such that the circuit board can be evenly heat-dissipated. When the radiator is an air-cooled radiator, the heat dissipation channel is a heat dissipation air duct; and when the radiator is a liquid-cooled radiator, the heat dissipation channel is an accommodation space formed by the radiator and used for accommodating the working chips.

In an embodiment, the radiator includes a heat dissipation main body 81 and heat dissipation fins 82, wherein the heat dissipation main body 81 includes a first surface and a second surface opposite to each other, wherein the first surface is connected to the heat dissipation fins 82, and the second surface is provided with bosses. The bosses are in contact with at least one of the thermal conductive elements, and the extension direction of the bosses is the same as the extension direction of the thermal conductive elements.

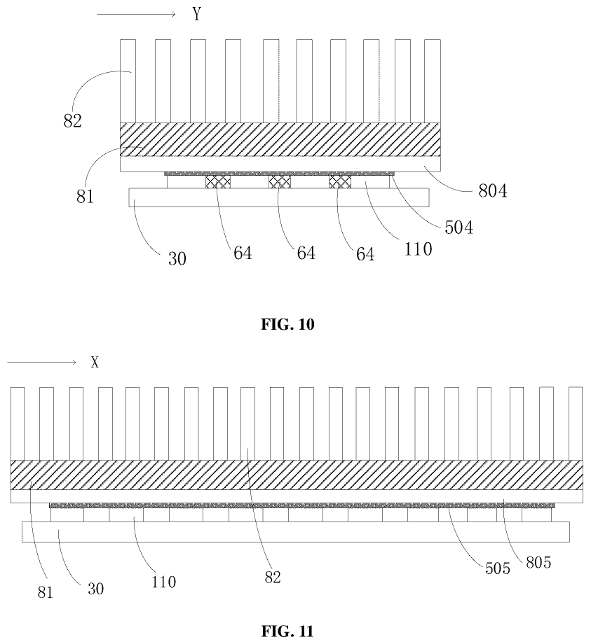

In an example, as shown in FIG. 7, a thermal conductive element 501 covers several working chips 110A, 110B and 110C, and regions between the working chips 110A, 110B and 110C, and the extension direction of bosses 801 is the same as the extension direction of the thermal conductive elements 501.

In another example, as shown in FIG. 8, the average spacing between the plurality of working chips 110 in a row direction X is greater than the average spacing between the plurality of working chips 110 in a column direction Y, and the thermal conductive elements 502 and the bosses 802 both extend in the column direction Y.

In still another example, as shown in FIG. 9, the average spacing between the plurality of working chips 110 in a row direction X is less than the average spacing between the plurality of working chips 110 in a column direction Y, and the thermal conductive elements 503 and the bosses 803 both extend in the row direction X.

In yet another example, as shown in FIG. 10, the heat dissipation direction is parallel to the row direction X, the spacing between adjacent working chips 110 is gradually increased in the heat dissipation direction, and the thermal conductive elements 504 and the bosses 804 both extend in the column direction Y.

In the next example, as shown in FIG. 11, the heat dissipation direction is parallel to the column direction Y, the spacing between adjacent working chips 110 is gradually increased in the heat dissipation direction, and the thermal conductive elements 505 and the bosses 805 both extend in the row direction X.

When the bosses are in contact with a certain thermal conductive element, the thermal conductive element may dissipate heat of the working chip 110 or a metal piece (described in detail below) covered by the thermal conductive element, thereby improving the heat dissipation characteristic of the circuit board. The extension direction of the bosses is the same as the extension direction of the thermal conductive elements, such that the bosses can be maximally in contact with the thermal conductive elements, thereby increasing the heat dissipation efficiency for the circuit board.

It should be noted that, in this embodiment, the number and size of the bosses are not limited, which may be differently configured as actually needed.

In an example, the plurality of working chips 110 are distributed in rows and columns, so as to form a plurality of working chip columns, and a thermal conductive element may cover one column of the working chips. Voltage regulation circuits (e.g., auxiliary power source circuits, which will be described in detail below) are further provided on the substrate 30, and components (e.g., auxiliary power source chips) of at least some of the voltage regulation circuits are distributed among the working chip columns. That is, the auxiliary power source chips may be distributed on the row spacing of the working chips. Further, a plurality of bosses are arranged corresponding to a plurality of working chip columns, such that grooves formed between adjacent bosses correspond to components of the voltage regulation circuits. Because the accommodation space formed by the groove can accommodate components with a certain height, when the components of the auxiliary power source circuits are selected, the limitation on the size of the components is reduced.

In another example, the plurality of working chips 110 are distributed in rows and columns, so as to form a plurality of working chip rows, and a thermal conductive element may cover one row of the working chips. Voltage regulation circuits (e.g., auxiliary power source circuits, which will be described in detail below) are further provided on the substrate 30, and components (e.g., auxiliary power source chips) of at least some of the voltage regulation circuits are distributed among the working chip rows. That is, the auxiliary power source chips may be distributed on the column spacing of the working chips. Further, a plurality of bosses are arranged corresponding to a plurality of working chip rows, such that grooves formed between adjacent bosses correspond to components of the voltage regulation circuits. Because the accommodation space formed by the groove can accommodate components with a certain height, when the components of the auxiliary power source circuits are selected, the limitation on the size of the components is reduced. In an embodiment, at least one metal piece is provided between the adjacent working chips connected in series, and a thermal conductive element between the adjacent working chips covers the metal piece between the adjacent working chips. The metal piece may be a copper piece or an aluminum piece welded on the substrate 30, and configured to dissipate heat for two adjacent working chips connected thereto, and reduce a voltage drop between the two adjacent working chips connected thereto. Thus, the working stability and reliability of the working chips are improved.

Connecting in series means that power supply for core voltages required by adjacent chips is provided in a series manner. For example, a plurality of chips are connected in series between a power source and the ground to supply the core voltages of the plurality of chips.

In an embodiment, the projection of a thermal conductive element on the substrate 30 corresponds to a metal piece between the adjacent working chips. Further, the projection of a boss on the substrate 30 corresponds to the metal piece.

In an example, as shown in FIG. 7, a metal piece 61 is provided between adjacent working chips 110A and 110B and between adjacent working chips 110B and 110C covered by a thermal conductive element 501, and the extension direction of the thermal conductive element 501 is the same as the extension direction of two metal pieces 61, such that the projection of the thermal conductive element 501 on the substrate 30 can cover the two metal pieces 61, and the projection of the boss 801 on the substrate 30 corresponds to the two metal pieces 61, thereby facilitating heat dissipation of the metal pieces 61.

In another example, as shown in FIG. 8, a metal piece 62 is provided between every two adjacent working chips 110, and the extension direction of the thermal conductive element 502 and the extension direction of metal pieces 62 are both column direction Y, such that the projection of the thermal conductive element 502 on the substrate 30 can cover the respective metal pieces 62, and the projection of the boss 802 on the substrate 30 can cover the respective metal pieces 62, thereby facilitating heat dissipation of the respective metal pieces 62.

In yet another example, as shown in FIG. 10, the heat dissipation direction is parallel to the row direction X, the spacing between adjacent working chips 110 is gradually increased in the row direction X, and the thermal conductive element 504 and metal pieces 64 both extend in the column direction Y, such that the projection of the thermal conductive element 504 on the substrate 30 can cover the respective metal pieces 64, and the projection of the boss 804 on the substrate 30 can cover the respective metal pieces 64, thereby facilitating heat dissipation of the respective metal pieces 64.

Exemplarily, the thickness of the metal piece is less than or equal to the thickness of each working chip. The thickness direction of the metal piece and the thickness direction of each working chip are the direction perpendicular to the substrate.

In the technical solution of this embodiment, by means of mutual cooperation of the bosses, the working chips and the metal pieces, a gap between the bosses and the substrate of the circuit board is reduced or eliminated, such that air perpendicular to the extension direction of the bosses cannot enter between the radiator and the circuit board, effectively avoiding dust accumulation between the radiator and the circuit board caused by long-term blowing, thereby effectively avoiding the effect of dust accumulation on the heat dissipation performance.

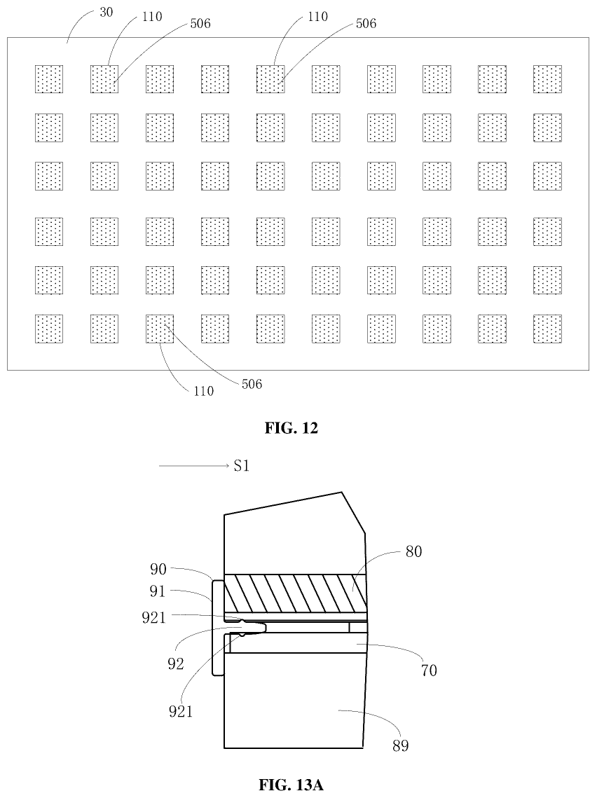

In an embodiment, as shown in FIG. 12, thermal conductive elements 506 and the working chips 110 are arranged in one-to-one correspondence, so as to dissipate heat for respective working chips 110. Each thermal conductive element 506 may cover some or all of the surface of corresponding working chip 110.

Exemplarily, the material of the thermal conductive elements may be silicone grease or silicone rubber, that is, the thermal conductive elements may be a silicone grease layer or a silicone rubber layer, and coated on or attached to the surfaces of the working chips 110.

In an embodiment, as shown in FIG. 1, the radiator is specifically an air-cooled radiator, and the radiator may be a radiator 80 and/or a radiator 89. The housing encloses a heat dissipation air duct, and the circuit board 70 and the radiator are both provided in the heat dissipation air duct; and the electronic device further includes a seal 90. The seal 90 is provided at end portions of the radiator and the circuit board close to an air inlet of the heat dissipation air duct, wherein the seal 90 extends in the direction perpendicular to the air direction of the heat dissipation air duct.

Exemplarily, the seal 90 is adhered to the end portions of the radiator and the circuit board close to the air inlet of the heat dissipation air duct.

Exemplarily, the seal 90 is provided between the radiator 80 and the circuit board 70, and is arranged close to the air inlet of the heat dissipation air duct, and the seal 90 extends in the direction S2 perpendicular to the heat dissipation direction. S1 represents the direction of the heat dissipation air duct, that is, the heat dissipation direction, and S2 represents the direction perpendicular to the heat dissipation direction. That is, the seal 90 is provided between the radiator 80 and the side of the circuit board 70 where the working chips 110 are provided.

It should be noted that, the structural details of the radiator 80 and the layout of the working chips 110 on the circuit board 70 are only intended to explain the structure of the seal 90 in this embodiment, and are not limited in this embodiment.

By providing the seal, the sealing performance of the radiator and the circuit board 70 at the air inlet can be improved, and moisture can be prevented from entering from a gap between the radiator 80 and the circuit board 70, so as to protect the working chips near the air inlet, and at the same time, air leakage can be avoided, thereby ensuring the amount of air passing through the radiator 80 and/or the radiator 89, so as to improve the heat dissipation performance of the circuit board 70.

In an embodiment, the plurality of working chips 110 are distributed in rows and columns, so as to form a plurality of working chip rows, and the extension direction (row direction) of the working chip rows is perpendicular to the air direction, that is, the extension direction of the working chip rows is S2.

Further, the extension length of the seal 90 is greater than the length of the working chip rows, that is, in the S2 direction, the length of the seal 90 is greater than the length of the working chip rows. The extension length of the seal 90 is less than the length of the circuit board 70 in the direction perpendicular to the air direction, that is, in the S2 direction, the length of the seal 90 is less than the length of the circuit board 70.

On this basis, the seal not only can prevent moisture from affecting the working chips, but also can provide avoidance for other structural parts at two ends of the circuit board.

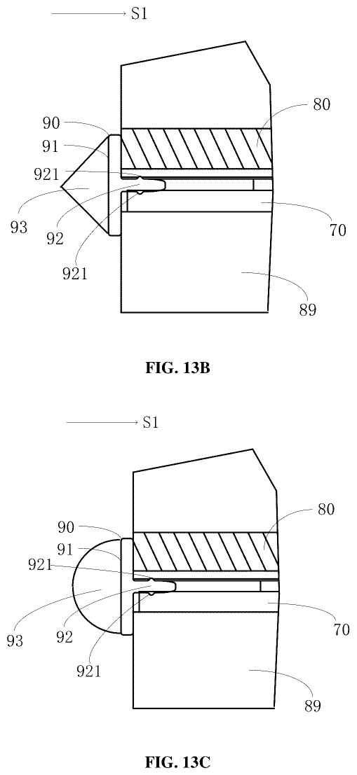

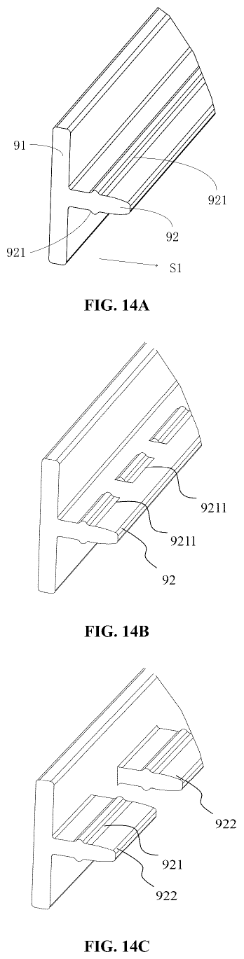

In an example, as shown in FIGS. 13A, 13B and 13C, and FIGS. 14A, 14B and 14C, the seal 90 includes a seal body 91 and a seal protruding portion 92. The seal body 91 abuts against the end portions of the circuit board 70 and the radiator 80 close to the air inlet; and the seal protruding portion 92 protrudes from the seal body 91 in the direction facing away from the air inlet, and is located at a gap between the radiator 80 and the circuit board 70. The thickness of the seal body 91 ranges from 0.8 mm to 1.2 mm, for example, the thickness of the seal body 91 may be 1 mm; and the height of the seal body 91 ranges from 7 mm to 9 mm, for example, the height of the seal body 91 may be 8 mm. The height direction of the seal 91 is perpendicular to the air direction, and the thickness direction of the seal 91 is parallel to the air direction. The thickness of the seal protruding portion 92 ranges from 0.5 mm to 1.5 mm, for example, the thickness of the seal protruding portion 92 may be 1 mm. The width of the seal protruding portion 92 ranges from 2.5 mm to 3.5 mm, for example, the width of the seal protruding portion 92 may be 3 mm. The thickness direction of the seal protruding portion 92 is perpendicular to the air direction, and the width direction of the seal protruding portion 92 is parallel to the air direction.

Exemplarily, the seal protruding portion 92 is an integrated member extending in the length direction of the seal body 91, or the seal protruding portion 92 includes a plurality of sub-protruding portions 922 arranged in the length direction of the seal body 91, and the length direction of the seal body 91 is perpendicular to the air direction.

Exemplarily, there are two sub-protruding portions 922 distributed at two ends of the seal body 91. Alternatively, there are three sub-protruding portions 922, two of which are distributed at two ends of the seal body 91, and the other of which is distributed at the middle portion of the seal body 91.

In an embodiment, as shown in FIGS. 13A, 13B and 13C, and FIGS. 14A, 14B and 14C, protrusion members 921 are formed on the seal protruding portion 92, and the protruding direction of the protrusion members 921 is perpendicular to the circuit board 70. There may be two protrusion members 921, which protrude towards the radiator 80 and the circuit board 70, respectively. On this basis, the entire seal 90 can be mounted and fixed by extending the seal protruding portion 92 into the gap for fastening without an additional mounting and fixing structure. The protruding height of the protrusion members 921 ranges from 0.2 mm to 0.3 mm. Exemplarily, the protruding height of the protrusion members 921 may be 0.25 mm.

Exemplarily, a protrusion member 921 is an integrated member extending in the length direction of the seal protruding portion 92, or a protrusion member 921 includes a plurality of sub-protrusion members 9211 arranged in the length direction of the seal protruding portion 92, and the length direction of the seal protruding portion 92 is perpendicular to the air direction. Exemplarily, the sub-protrusion members 9211 may be in a long strip shape or a hemispherical shape, which is not limited in the present application.

Exemplarily, the thickness of the seal protruding portion 92 is less than the height of the gap between the radiator 80 and the circuit board 70; the sum of the thickness of the seal protruding portion 92 and the height of the protrusion members 921 (or the height of the sub-protrusion members 9211) is greater than the height of the gap between the radiator 80 and the circuit board 70; and the minimum thickness of the seal protruding portion 92 and protrusion members 921 after compression is less than the height of the gap between the radiator 80 and the circuit board 70. For example, the sum of the minimum compressed height of the protrusion members 921 and the thickness of the seal protruding portion 92 is less than the height of the gap between the radiator 80 and the circuit board 70. Here, the thickness direction of the seal protruding portion 92 is perpendicular to the air direction, and the height direction of the protrusion members 921 is perpendicular to the air direction.

In an embodiment, an air guide portion 93 is formed on the surface of the seal body 91 facing away from the seal protruding portion 92, the cross section of the air guide portion 93 is in a protruding shape, and the protruding direction of the protruding shape is opposite to the protruding direction of the seal protruding portion 92. For example, the cross section of the air guide portion 93 is in a triangular or semicircular shape. The cross section is perpendicular to the circuit board. The surface of the air guide portion 93 are inclined towards the radiator 80 and the radiator 89 respectively, so as to guide air at the air inlet to the radiator 80 and the radiator 89, thereby increasing the amount of air entering the radiator and improving the heat dissipation performance.

In an embodiment, the radiator 89 is provided on the side of the circuit board 70 where the working chips are not provided, and the seal body 91 is in contact with the end portion of the radiator 80 close to the air inlet, and in contact with the end portion of the radiator 89 close to the air inlet.

Exemplarily, the seal may be an elastic member, such as a rubber member, so as to facilitate installation of the seal.

In another example, a seal protruding towards the circuit board 70 is formed at the end portion of the radiator 80 close to the air inlet, and the seal is in contact with the end portion of the circuit board 70 close to the air inlet. That is, the seal may be integrally formed with the radiator 80.

In an embodiment, a signal transmission circuit is provided on the substrate 30, and the circuit board is a single-layer circuit board. The circuit board further includes at least one bridging element provided at an intersection of circuit connection lines, wherein the bridging element includes a zero-ohm resistor and/or a zero-ohm metal patch, thereby facilitating wiring of the signal transmission circuit on the substrate 30. In a case where the radiator is assembled with the circuit board, the zero-ohm resistor on the circuit board is provided opposite to a recess portion on the radiator. Because the zero-ohm resistor has a low cost, the zero-ohm resistor may be provided if the assembly space permits, thereby reducing the cost. Exemplarily, the recess portion may be a groove between adjacent bosses of the radiator.

In an embodiment, a signal transmission circuit is provided on the substrate 30. The electronic device in this embodiment may further include a control board 300.

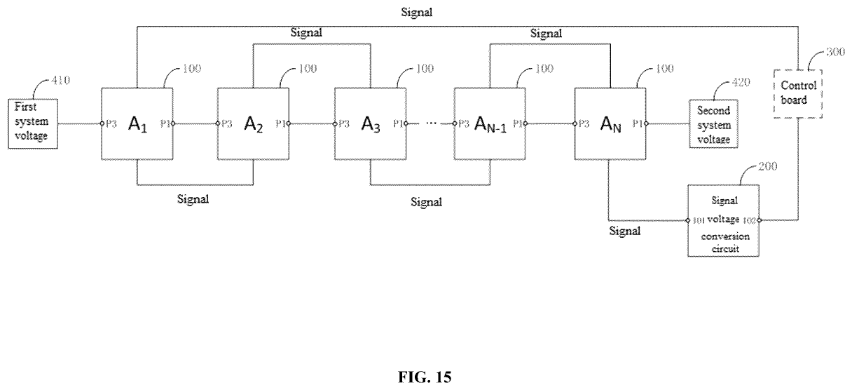

As shown in FIG. 15, the signal transmission circuit includes N stages of working circuits 100 and a signal voltage conversion circuit 200. For ease of illustration, as shown in FIG. 15, the N stages of working circuits 100 are numbered as A₁, A₂, A₃, . . . , A_{N-1} and A_{N}, respectively, where N is an integer greater than 1.

Each stage of working circuit includes a working chip, and the working chip may be various computing chips or control chips, so as to implement core functions such as a corresponding computing function or a control function. There may be one or more working chips in the same stage of working circuit 100. Exemplarily, a plurality of working chips in the same stage of working circuit 100 may be connected in parallel.

Further, the number of working chips in the stages of working circuits 100 may be equal or not equal, which may be configured as actually needed, and is not limited in this embodiment.

Exemplarily, each working chip in the current stage of working circuit performs computing according to an input signal of the current stage of working circuit, and generates an output signal of the current stage of working circuit according to a computing result. The input signal of the current stage of working circuit comes from the output signal of the previous stage of working circuit, and the output signal of the current stage of working circuit is output to the next stage of working circuit.

Further, the N stages of working circuits 100 are connected in series between a first system voltage 410 and a second system voltage 420, the second system voltage 420 is higher than the first system voltage 410, and a voltage difference between the first system voltage 410 and the second system voltage 420 provides a series voltage for the N stages of working circuits 100 connected in series, thereby providing a core working voltage for the core function of each stage of working circuit 100. As shown in FIG. 15, a first-stage working circuit A₁ is connected to the first system voltage 410, and an Nth-stage working circuit A_{N} is connected to the second system voltage 420.

Exemplarily, the first system voltage 410 may be a system grounding voltage, and the second system voltage 420 may be a system power source voltage. For example, when the N stages of working circuits 100 are applied to an electronic device, the first system voltage 410 is provided by a grounding end of the electronic device, and the second system voltage 420 is provided by the electronic device connecting to a power source.

It should be noted that, a signal transmission direction of the N stages of working circuits 100 is not limited in this embodiment, for example, transmission may be performed in the direction from A₁ to A_{N}, and may also be performed in the direction from A_{N} to A₁.

The control board 300 is connected to the first-stage working circuit A₁ and the signal voltage conversion circuit, respectively. Specifically, a first input/output (I/O) end IO1 of the signal voltage conversion circuit 200 is connected to the Nth-stage working circuit A_{N}, and a second input/output end IO2 of the signal voltage conversion circuit is connected to the control board 300.

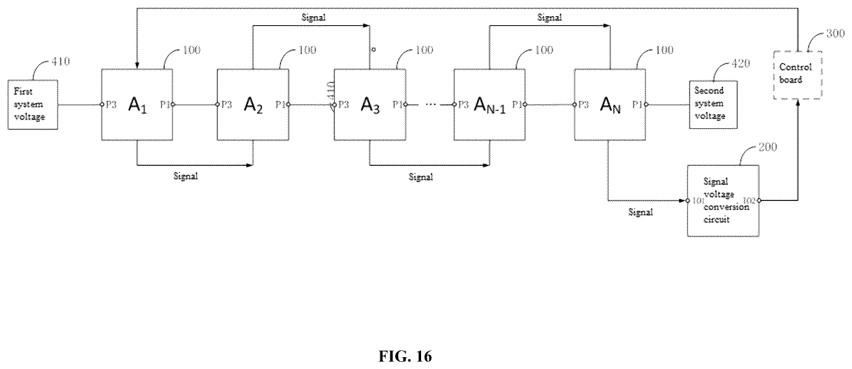

In the first embodiment, as shown in FIG. 16, the signal voltage conversion circuit 200 is configured to perform voltage conversion on working circuit signals sent by the N stages of working circuits 100 and then send same to the control board 300.

Specifically, the control board 300 sends its own control board signal to the N stages of working circuits 100; the N stages of working circuits work according to the control board signal, generate a working circuit signal according to a final working result, and then send the working circuit signal to the signal voltage conversion circuit 200; and the signal voltage conversion circuit 200 performs voltage conversion on the working circuit signal and sends same to the control board 300.

The working circuit signal may be a data signal such as a computing result, and the control board signal may be a data signal such as a data source. For example, the N stages of working circuits perform computing or operation on the data source in the control board signal to obtain a computing result.

Exemplarily, in the embodiment shown in FIG. 16, the first-stage working circuit A₁ is configured to receive a control board signal of the control board 300, and the signal voltage conversion circuit 200 is configured to send a working circuit signal of the Nth-stage working circuit A_{N} to the control board 300. That is, the signal transmission direction of the N stages of working circuits 100 is transmission in the direction from A₁ to A_{N}.

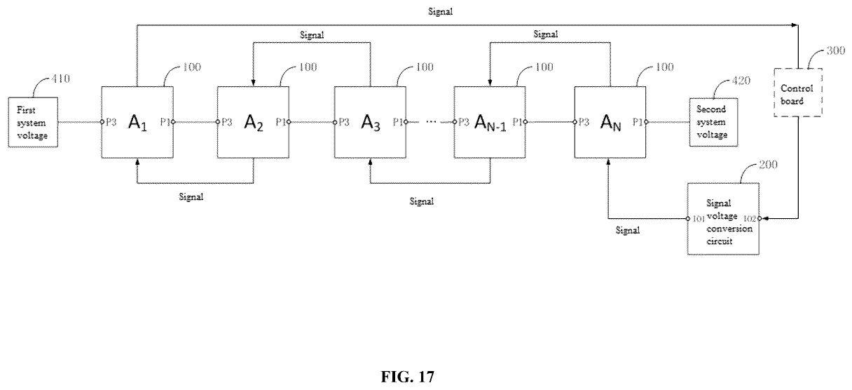

In the second embodiment, as shown in FIG. 17, the signal voltage conversion circuit 200 is configured to perform voltage conversion on a control board signal sent by the control board 300 and then send same to the N stages of working circuits 100.

Specifically, the control board 300 sends its own control board signal to the signal voltage conversion circuit 200; the signal voltage conversion circuit 200 performs voltage conversion on the control board signal and then sends same to the N stages of working circuits 100; and the N stages of working circuits work according to the voltage-converted control board signal, generate a working circuit signal according to a final working result (for example, a computing result), and send the working circuit signal to the control board 300.

Exemplarily, in the embodiment shown in FIG. 17, the control board 300 sends a control board signal to the signal voltage conversion circuit 200, the signal voltage conversion circuit 200 is configured to send a voltage-converted control board signal to the Nth-stage working circuit A_{N}, and the first-stage working circuit A₁ is configured to send a working circuit signal to the control board 300. That is, the signal transmission direction of the N stages of working circuits 100 is transmission in the direction from A_{N} to A₁.

In this embodiment, the signal voltage conversion circuit 200 may implement parallel transmission of a control board signal and a working circuit signal between the N stages of working circuits 100 and the control board 300, thereby increasing the working efficiency.

It should be noted that the signal voltage conversion circuit 200 may transmit one or more signals. That is, the signal voltage conversion circuit 200 may implement parallel transmission of multiple paths of control board signals and working circuit signals of different waveforms, and correspondingly, the first input/output end IO1 and the second input/output end IO2 may be in one group or multiple groups.

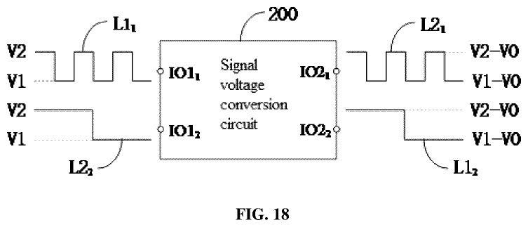

In an example shown in FIG. 18, the signal voltage conversion circuit 200 may implement signal transmission of two paths, and correspondingly, there are two groups of the first input/output ends IO1 and the second input/output ends IO2, that is, IO1₁ and IO2₁, and IO1₂ and IO2₂. For ease of illustration, in this example, the signal transmission direction of the N stages of working circuits 100 is the direction from the first system voltage 410 to the second system voltage 420, that is, in the signal voltage conversion circuit 200, the first input/output end IO1₁ and IO1₂ is configured to perform voltage conversion on the working circuit signal in the Nth-stage working circuit, and then a voltage-converted working circuit signal is output from the second input/output end IO2₁ and IO2₂, and is sent to the control board 300.

In the example shown in FIG. 18, L1₁ represents a waveform of a working circuit signal input to the first input/output end IO1₁, and L2₁ represents a waveform of a voltage-converted working circuit signal output by the second input/output end IO2₁. Exemplarily, the voltage conversion function of the signal voltage conversion circuit 200 is to implement a voltage drop with voltage difference V0. Furthermore, in L1₁, a low level is V1, and a high level is V2; and in L2₁, a low level is V1-V0, and a high level is V2-V0.

Further, L1₂ represents a waveform of a control board signal input to the first input/output end IO1₂, and L2₂ represents a waveform of a voltage-converted control board signal output by the second input/output end IO2₂. In L1₁, a low level is V1, and a high level is V2; and in L2₁, a low level is V1-V0, and a high level is V2-V0.

Exemplarily, V0 may be 14V, and V1 and V2 are related to the transmission demand of working circuit signals, for example, may be 1.2V, 1.8V, 2.5V, or the like, which is not limited in this embodiment. In addition, the waveform in FIG. 18 is merely an example, and is not limited thereto.

Further, the signal transmission circuit in this embodiment may further include a plurality of voltage regulation circuits 430. The plurality of voltage regulation circuits 430 are connected to at least some stages of working circuits 100 in one-to-one correspondence, that is, the number of the voltage regulation circuits 430 is less than or equal to N. Each voltage regulation circuit 430 is configured to provide at least one regulation voltage for the connected working circuit 200.

Exemplarily, the regulation voltage may provide an auxiliary function voltage for a specific function other than a core function of the working circuit 200, for example, as an input/output voltage or a clock signal voltage of the working circuit 200.

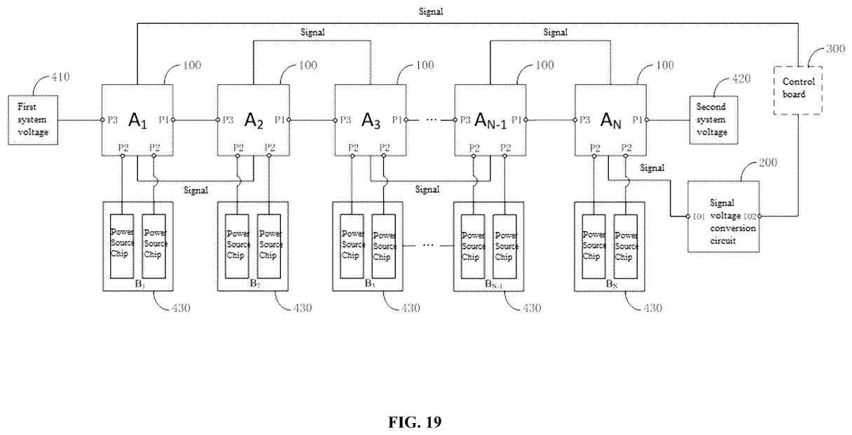

Exemplarily, as shown in FIG. 19, the number of the voltage regulation circuits 430 is equal to N. For ease of illustration, the N voltage regulation circuits 430 are B₁, B₂, B₃, . . . , B_{N-1} and B_{N}, respectively. B₁ is connected to A₁ so as to provide at least one regulation voltage for A₁; B₂ is connected to A₂ so as to provide at least one regulation voltage for A₂; . . . B_{N} is connected to A_{N} so as to provide at least one regulation voltage for A_{N}.

Based on the description above, for each stage of working circuit 100, the power supply end thereof may include a series circuit power supply end P1, and may also include a regulation voltage power supply end P2, and there may be multiple regulation voltage power supply ends P2; the grounding end thereof is a serial port P3 close to the connection end of the first system voltage 410.

Further, each voltage regulation circuit 430 includes at least one power source chip. It should be noted that FIG. 19 shows an example with two power source chips and two regulation voltage power supply ends P2, but the present invention is not limited thereto.

When each voltage regulation circuit 430 include one power source chip, one regulation voltage may be provided for the connected working circuit 200, that is, the number of the regulation voltage power supply ends P2 of the connected working circuit 200 is 1. When each voltage regulation circuit 430 includes M power source chips, M or more regulation voltages may be provided for the connected working circuit 200, that is, the number of the regulation voltage power supply ends P2 of the connected working circuit 200 is greater than or equal to M. For example, M or more regulation voltages may be output in combination by using a series-parallel connection relationship among a plurality of power source chips. That is, the number of the regulation voltages is positively correlated with the number of the power source chips. Furthermore, the M regulation voltages may be equal or not equal, which is not limited in this embodiment.

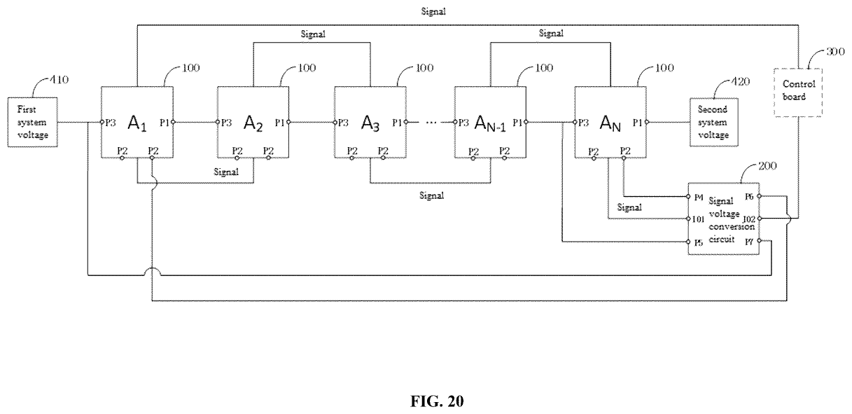

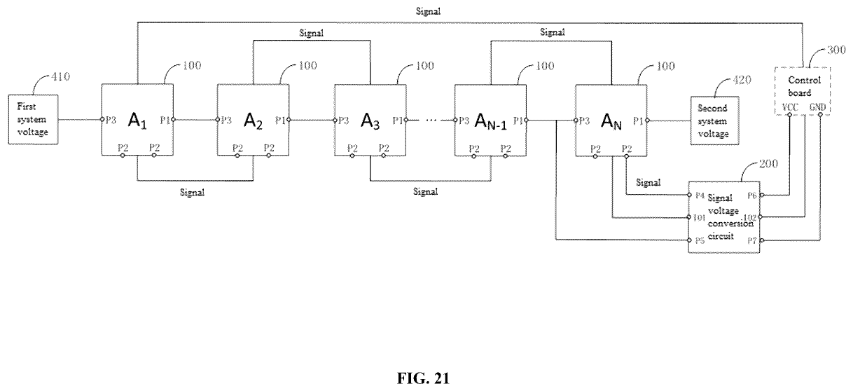

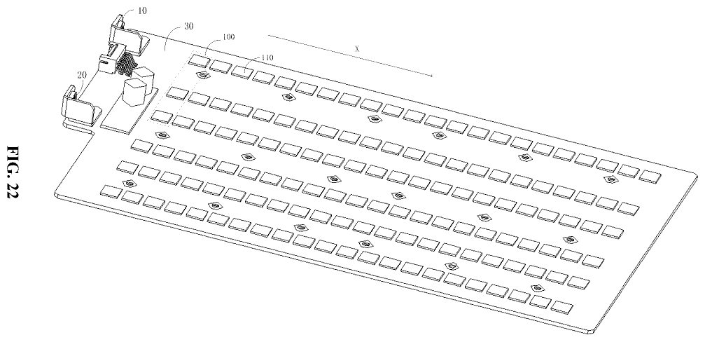

In an embodiment, the signal voltage conversion circuit 200 includes a first power supply end P4 and a first grounding end P5. The first power supply end P4 is connected to any regulation voltage power supply end P2 of the Nth-stage working circuit A_{N}, and the first grounding end P5 is connected to the grounding end P3 of the Nth-stage working circuit A_{N}, as shown in FIGS. 20 and 21.

Further, the signal voltage conversion circuit 200 further includes a second power supply end P6 and a second grounding end P7. In an example, as shown in FIG. 20, the second power supply end P6 and the second grounding end P7 are connected to any regulation voltage power supply end P2 of the first-stage working circuit A₁ and the grounding end P3 of the first-stage working circuit A₁, respectively. In another example, as shown in FIG. 21, the second power supply end P6 and the second grounding end P7 are connected to a power supply end VCC and a grounding end GND of the control board 300, respectively.

That is, the power supply of the signal voltage conversion circuit 200 may be configured as actually needed, so as to adapt to circuits of different line layouts.

According to the technical solution of this embodiment, bidirectional parallel signal transmission between the working circuits and the control board can be implemented, thereby increasing the signal transmission efficiency.

Further, the substrate 70 is provided with a first system voltage interface 10 and a second system voltage interface 20. The first system voltage interface 10 and the second system voltage interface 20 are respectively connected to a power source and a system grounding end, so as to provide a first system voltage 410 and a second system voltage 420, respectively.

Exemplarily, as shown in FIG. 22, N stages of working circuits 100 are arranged in the length direction X of the circuit board. In an example, each stage of working circuit 100 includes three parallel working chips 110. That is to say, in the positive direction of X, the first-stage working circuit to the (N/2)th-stage working circuit are connected in series sequentially, and in the negative direction of X, the (N/2+1)th-stage working circuit to the Nth-stage working circuit are connected in series sequentially, and the (N/2)th-stage working circuit is connected in series to the (N/2+1)th-stage working circuit. In this way, the first-stage working circuit to Nth-stage working circuit are connected in series sequentially between the first system voltage interface 10 and the second system voltage interface 20.

Other configurations of the circuit board or the electronic device in the foregoing embodiments may adopt various technical solutions that are known by persons of ordinary skill in the art now and in the future, and are not described in detail herein again.

The technical solutions of the embodiments of the present disclosure can improve the heat dissipation performance and power supply performance of a circuit board.

In the illustration of the present disclosure, it should be understood that, orientation or position relationships indicated by terms such as “center”, “longitudinal”, “lateral”, “length”, “width”, “thickness”, “up”, “down”, “front”, “rear”, “left”, “right”, “vertical”, “horizontal”, “top”, “bottom”, “inner”, “outer”, “clockwise”, “counterclockwise”, “axial”, “radial” and “circumferential” are orientation or position relationships based on those illustrated in the drawings, which are only used to facilitate illustration of the present disclosure and simplify the illustration, and do not indicate or imply that the device or element referred to must have a specific orientation, or be configured or operated in a specific orientation, and therefore cannot be construed as limitations to the present disclosure.

In addition, terms such as “first” and “second” are used herein only for purposes of illustration and are not intended to indicate or imply relative importance or to implicitly state the number of indicated technical features. Thus, the features defined by “first” and “second” may explicitly or implicitly include one or more of the features. In the illustration of the present disclosure, “a plurality of” means two or more than two, unless specified otherwise.

In the present disclosure, unless specified or defined otherwise, terms such as “mount”, “link”, “connect”, and “fix” should be understood in a broad sense, and may be, for example, fixed connections, detachable connections, or integral forms, may be mechanical connections, electrical connections, or communication connections, may be direct connections, or indirect connections via intermediaries, and may be communications between the interior of two elements, or interactive relationships of two elements. The specific meanings of the above terms in the present disclosure can be understood by those skilled in the art according to specific situations.

In the present disclosure, unless specified or defined otherwise, a first feature being “above” or “below” a second feature may include an embodiment in which the first feature is in direct contact with the second feature, and may also include an embodiment in which the first feature and the second feature are not in direct contact with each other, but are contacted via an additional feature therebetween. Furthermore, a first feature being “over”, “above”, or “on” a second feature may include an embodiment in which the first feature is right above or diagonally above the second feature, or just means that the first feature is at a level higher than the second feature. A first feature being “underneath”, “below” or “under” a second feature may include an embodiment in which the first feature is right below or diagonally below the second feature, or just means that the first feature is at a level lower than the second feature.

The above disclosure provides many different embodiments or examples for implementing different structures of the present disclosure. In order to simplify the present disclosure, the components and configurations of specific examples are described above. Of course, they are merely examples and are not intended to limit the present disclosure. In addition, reference numerals and/or letters may be repeated in various examples in the present disclosure for the purpose of simplicity and clarity, which do not in itself indicate relationships between the various embodiments and/or arrangements discussed.

The content above merely relates to specific embodiments of the present disclosure, but are not intended to limit the scope of protection of the present disclosure. Any person skilled in the art can easily figure out various modifications or replacements within the technical scope disclosed in the present disclosure, and all these modifications or replacements shall fall within the scope of protection of the present disclosure. Therefore, the scope of protection of the present disclosure shall be subject to the scope of protection of the claims.

What is claimed is:

1. An electronic device, comprising:
a housing;
working assemblies mounted in the housing, wherein each working assembly comprises a circuit board and a radiator, the circuit board comprising a substrate and a plurality of working chips provided on the substrate; and the working assemblies are detachably mounted within the housing;
a control board connected to the circuit board; and
a power source configured to supply power to the circuit board.

2. The electronic device according to claim 1, further comprising:
a plurality of thermal conductive elements, wherein each thermal conductive element covers at least two adjacent working chips and a region between the adjacent working chips; and
the radiator comprises a heat dissipation main body and heat dissipation fins, wherein the heat dissipation main body comprises a first surface and a second surface opposite to each other, the first surface is connected to the heat dissipation fins, the second surface is provided with a plurality of bosses, the bosses are in contact with at least one of the thermal conductive elements, and an extension direction of the bosses is the same as an extension direction of the thermal conductive elements.

3. The electronic device according to claim 2, wherein the plurality of working chips are distributed in rows and columns, an average spacing between the plurality of working chips in a row direction is greater than an average spacing between the plurality of working chips in a column direction, and the thermal conductive elements extend in the column direction.

4. The electronic device according to claim 3, wherein the plurality of working chips form a plurality of working chip columns, voltage regulation circuits are further provided on the substrate, and components of at least some of the voltage regulation circuits are distributed among the working chip columns.

5. The electronic device according to claim 2, wherein the plurality of working chips are distributed in rows and columns, an average spacing between the plurality of working chips in a row direction is less than an average spacing between the plurality of working chips in a column direction, and the thermal conductive elements extend in the row direction.

6. The electronic device according to claim 5, wherein the plurality of working chips form a plurality of working chip rows, voltage regulation circuits are further provided on the substrate, and components of at least some of the voltage regulation circuits are distributed among the working chip rows.

7. The electronic device according to claim 2, wherein the thermal conductive elements extend in a direction perpendicular to a heat dissipation direction.

8. The electronic device according to claim 7, wherein in the heat dissipation direction, spacing between at least some of adjacent working chips is gradually increased.

9. The electronic device according to claim 8, wherein the housing encloses a heat dissipation air duct, the circuit board and the radiator are both provided in the heat dissipation air duct, and the heat dissipation direction is an air direction of the heat dissipation air duct, and wherein the spacing between at least some of adjacent working chips is positively correlated with a distance from the at least some of adjacent working chips to an air inlet of the heat dissipation air duct; or
wherein an inner cavity of the radiator accommodates a heat dissipation medium, and the heat dissipation direction is a flowing direction of the heat dissipation medium.

10. The electronic device according to claim 2, wherein the respective working chips have the same size, and/or the respective working chips have the same heating area.

11. The electronic device according to claim 10, wherein at least one metal piece is provided between the adjacent working chips connected in series, and a thermal conductive element between the adjacent working chips covers the metal piece,
wherein a projection of a boss on the substrate corresponds to the metal piece,
wherein a projection of the thermal conductive element on the substrate corresponds to the metal piece between the adjacent working chips, and
wherein a thickness of the metal piece is less than or equal to a thickness of a working chip, and a thickness direction of the metal piece and a thickness direction of the working chip are perpendicular to the substrate.

12. The electronic device according to claim 1, wherein the housing encloses a heat dissipation air duct, and the circuit board and the radiator are both provided in the heat dissipation air duct;
the electronic device further comprises a seal provided at end portions of the radiator and the circuit board close to an air inlet of the heat dissipation air duct, wherein the seal extends in a direction perpendicular to an air direction of the heat dissipation air duct.

13. The electronic device according to claim 12, wherein the seal comprises:
a seal body abutting against the end portions of the circuit board and the radiator close to the air inlet; and
a seal protruding portion protruding from the seal body and located at a gap between the radiator and the circuit board,
wherein the seal protruding portion is an integrated member extending in a length direction of the seal body, and the length direction of the seal body is perpendicular to the air direction; or
wherein the seal protruding portion comprises a plurality of sub-protruding portions arranged in a length direction of the seal body, and the length direction of the seal body is perpendicular to the air direction.

14. The electronic device according to claim 13, wherein protrusion members are formed on the seal protruding portion, and a protruding direction of the protrusion members is perpendicular to the circuit board,
wherein a protrusion member is an integrated member extending in a length direction of the seal protruding portion, and the length direction of the seal protruding portion is perpendicular to the air direction, or
wherein a protrusion member comprises a plurality of sub-protrusion members arranged in a length direction of the seal protruding portion, and the length direction of the seal protruding portion is perpendicular to the air direction.

15. The electronic device according to claim 13, wherein an air guide portion is formed on a surface of the seal body facing away from the seal protruding portion, and
wherein a cross section of the air guide portion is in a triangular or semicircular shape, and the cross section of the air guide portion is perpendicular to the circuit board.

16. The electronic device according to claim 12, wherein a seal protruding towards the circuit board is formed at an end portion of the radiator close to the air inlet, and the seal is in contact with the end portion of the circuit board close to the air inlet,
wherein the plurality of working chips form a plurality of working chip rows, an extension direction of the working chip rows is perpendicular to the air direction, and an extension length of the seal is greater than a length of the working chip rows, and
wherein an extension length of the seal is less than a length of the circuit board in the direction perpendicular to the air direction.

17. The electronic device according to claim 1, wherein the circuit board is a single-layer circuit board, and the circuit board further comprises:
at least one bridging element provided at an intersection of circuit connection lines, wherein the bridging element comprises a zero-ohm resistor and/or a zero-ohm metal patch, and
wherein the zero-ohm resistor is provided opposite to a recess portion on the radiator.

18. The electronic device according to claim 1, further comprising a control board, and a signal transmission circuit provided on the substrate, wherein the signal transmission circuit comprises:
N stages of working circuits connected in series, wherein each working circuit respectively comprises at least one working chip, where N is an integer greater than 1, a first-stage working circuit is connected to a first system voltage, and an Nth-stage working circuit is connected to a second system voltage, the second system voltage being higher than the first system voltage; and
a signal voltage conversion circuit, wherein a first input/output end of the signal voltage conversion circuit is connected to the Nth-stage working circuit, and a second input/output end of the signal voltage conversion circuit is connected to the control board;
wherein the signal voltage conversion circuit is configured to perform voltage conversion on a control board signal sent by the control board and then send the converted control board signal to the N stages of working circuits; alternatively, the signal voltage conversion circuit is configured to perform voltage conversion on working circuit signals sent by the N stages of working circuits and then send the converted working circuit signals to the control board.

19. The electronic device according to claim 18, wherein the first-stage working circuit is configured to receive the control board signal, and the signal voltage conversion circuit is configured to send a working circuit signal of the Nth-stage working circuit to the control board.

20. The electronic device according to claim 18, wherein the signal transmission circuit further comprises:
a plurality of voltage regulation circuits connected to at least some stages of working circuits in one-to-one correspondence, wherein each voltage regulation circuit respectively comprises at least one power source chip, and is configured to provide at least one regulation voltage for the connected working circuit,
wherein the signal voltage conversion circuit comprises a first power supply end and a first grounding end, which are respectively connected to a regulation voltage power supply end of the Nth-stage working circuit and a grounding end of the Nth-stage working circuit, and
wherein the signal voltage conversion circuit further comprises a second power supply end and a second grounding end, which are respectively connected to a power supply end of the control board and a grounding end of the control board, or, wherein the signal voltage conversion circuit further comprises a second power supply end and a second grounding end, which are respectively connected to a regulation voltage power supply end of the first-stage working circuit and a grounding end of the first-stage working circuit.
